(19) United States
(12) Patent Application Publication
(10) Pub. No.: US 2022/0404703 A1
(43) Pub. Date: Dec. 22, 2022

(54) SEMICONDUCTOR DEVICE AND IMPRINT METHOD

(71) Applicant: Kioxia Corporation, Tokyo (JP)

(72) Inventors: Kasumi OKABE, Aichi Nagoya (JP); Takeshi HIGUCHI, Yokohama Kanagawa (JP)

(73) Assignee: Kioxia Corporation, Tokyo (JP)

(21) Appl. No.: 17/694,281

(22) Filed: Mar. 14, 2022

(30) Foreign Application Priority Data
Jun. 17, 2021 (JP) 2021-100771

(51) Int. Cl. G03F 7/075; G03F 7/00; G03F 7/16; G03F 7/11; H01L 21/02

(52) U.S. Cl. CPC G03F 7/0757; G03F 7/0002; G03F 7/162; G03F 7/11; H01L 21/02126; H01L 21/02167; B82Y 40/00

(57) ABSTRACT

In general, according to one embodiment, there is provided a semiconductor device including a substrate, an insulating layer formed above the substrate, and a conductive layer provided in the insulating layer. The insulating layer includes at least one cellulose fiber.

### CROSS-REFERENCE TO RELATED APPLICATIONS

This application is based upon and claims the benefit of priority from Japanese Patent Application No. 2021-100771, filed Jun. 17, 2021, the entire contents of which are incorporated herein by reference.

### FIELD

Embodiments described herein relate generally to a composition, an imprint method, and a semiconductor device.

### BACKGROUND

Imprintlithography (in particular, nano-imprintlithography) is known as a technique for manufacturing a semiconductor integrated circuit. The imprintlithography is a technique for pressing a template in which a pattern of a semiconductor integrated circuit is formed to a composition applied to a semiconductor substrate, thereby transferring the pattern formed in the template into the composition.

In the case of using the composition into which a pattern is transferred by imprintlithography as an insulator of a semiconductor device, the insulator requires a mechanical strength that can withstand chemical mechanical polishing (CMP).

### BRIEF DESCRIPTION OF THE DRAWINGS

FIG. 1 is a schematic view showing a sectional structure of a semiconductor device according to one embodiment.

FIG. 2 is a schematic view showing a step of an imprint method according to another embodiment.

FIG. 3 is a schematic view showing a step of manufacturing the semiconductor device.

FIG. 4 is a schematic view showing another step of manufacturing the semiconductor device.

### DETAILED DESCRIPTION

In general, according to one embodiment, there is provided a semiconductor device including a substrate, an insulating layer formed above the substrate, and a conductive layer provided in the insulating layer. The insulating layer includes at least one cellulose fiber.

Hereinafter, embodiments will be described with reference to the accompanying drawings. In the following description, components with substantially the same functionalities and configurations will be referred to with the same reference numerals, and repeated descriptions may be omitted. The figures are schematic, and the relations between the thickness and the area of a plane of a layer and ratios of thicknesses of layers may differ from actual ones. Moreover, the figures may include components which differ in relations and/or ratios of dimensions in different figures. The entire description of an embodiment is applicable to another embodiment unless otherwise expressly or implicitly excluded. Each embodiment illustrates the device and method for materializing the technical idea of that embodiment, which does not specify the quality of the material, shape, structure, arrangement of components, etc. to the following.

### First Embodiment

The first embodiment is a curable composition for imprinting that includes at least one cellulose fiber and photo-curable resin. First, components of the composition will be explained.

The cellulose fiber includes at least one cellulose molecule. The cellulose fiber is not limited to a specific type, but for example, may be of a type in which a phosphate group is introduced in at least a part of a hydroxy group (OH group) of the cellulose fiber. When a phosphate group is introduced in an OH group, the OH group is phosphate-esterified. The OH group is prone to inhibit an optical radical polymerizing reaction. In the cellulose fiber in which a phosphate group has been introduced, since the OH group has been phosphate-esterified, the possibility of a polymerizing reaction being inhibited by the OH group can be reduced. Furthermore, the cellulose fiber in which a phosphate group has been introduced does not easily cause charging to a negative ion, which is caused by the OH group or the like, and does not include a metal ion such as Na, which is a counter ion. Therefore, it is possible to prevent a foreign metal substance from being mixed into a molded product obtained from the composition or a semiconductor device including the molded product.

The cellulose fiber in which a phosphate group has been introduced is obtained, for example, by reacting a compound containing a phosphate group and/or a salt thereof (first material) with a fiber material containing cellulose, under the presence of urea and/or a derivative thereof (second material). After the phosphate group has been introduced, the cellulose fiber may be subjected to a fine process to a nano-level, if necessary. The fiber material containing cellulose may be, but is not limited to, papermaking pulp; cotton-based pulp, such as cotton linter or cotton lint; non-wood pulp such as linen, straw, or bagasse; or cellulose isolated from sea squirt, seaweed, or the like. The first material may be, but is not limited to, a phosphoric acid, a lithium salt of a phosphoric acid, a sodium salt of a phosphoric acid, a potassium salt of a phosphoric acid, an ammonium salt of a phosphoric acid, or the like. The second material may be, but is not limited to, urea, thiourea, biuret, phenylurea, benzylurea, dimethylurea, diethylurea, tetramethylurea, benzolein urea, hydantoin, or the like.

The at least one cellulose fiber may be, for example, at least one cellulose nanofiber. Since the at least one cellulose nanofiber allows for formation of a three-dimensional structure in which at least one fiber is arranged three-dimensionally, they can improve the mechanical strength (for example, a coefficient of elasticity) of a cured material obtained by curing the composition. Furthermore, the easy fitting of the at least one cellulose nanofiber into a fine pattern in nanometer order provides the advantage of easy formation of that fine pattern. Thus, the composition including the at least one cellulose nanofiber is suitable for nano-imprintlithography.

One of the at least one cellulose fiber may have a diameter of 3 nm or greater and 15 nm or smaller. By setting the diameter to 15 nm or smaller, the cellulose fiber can be easily fitted in a fine pattern of a nanometer order. The cellulose fiber having a smaller diameter tend to fit into the fine pattern more easily; therefore, the lower limit value of the diameter approximates to a minimum value of the diameter of a single cellulose fiber. The minimum value is, for example, 3 nm. Therefore, setting the diameter to 3 nm or greater and 15 nm or smaller can contribute to improvement of the mechanical strength of a layer structure having a fine pattern.

Whether or not cellulose fiber is present in the composition can be confirmed through, for example, transmission electron microscope (TEM) observation. The number average fiber diameter of cellulose fiber in the composition and the diameter of cellulose fiber in the composition can be obtained by, for example, a laser diffraction-type particle size distribution measurement device. Whether or not cellulose fiber is present in the cured material obtained by curing the composition can be confirmed through, for example, TEM observation. The fiber diameter of cellulose fiber present in the cured material can be measured through, for example, TEM observation.

The content of at least one cellulose fiber can be 1 part by mass to 50 parts by mass with respect to 100 parts by mass of photo-curable resin. The mechanical strength of the cured material obtained from the composition can be improved by setting the content to 1 part by mass or more. The viscosity and coating property of the composition can be within a range adapted to an imprint method by setting the content to 50 parts by mass or less. Thus, setting the content to 1 part by mass to 50 parts by mass is favorable for improvement of the mechanical strength of molded material (cured material) obtained by the imprint method.

The photo-curable resin is not particularly limited but may be, for example, an acrylate monomer and a silicon (Si) containing acrylate monomer. The types of the photo-curable resin used in the embodiment can be one, two or more. It is preferable to use a silicon (Si) containing acrylate monomer. It is possible to use both an acrylate monomer and a silicon (Si) containing acrylate monomer. The silicon (Si) containing acrylate monomer can be, for example, a reaction product of silicone resin and (meta)acrylic resin. Specifically, examples of the silicon (Si) containing acrylate monomer include a graft resin in which silicone resin is introduced to a side chain of (meta)acrylate. Examples of the acrylate monomer include phenylethylene glycol diacrylate, and the like.

The composition can include components other than the at least one cellulose fiber and the photo-curable resin. Examples of other components include a solvent, a photoinitiator, a polymerization inhibitor, and the like.

The type of the solvent is not particularly limited. Examples of the solvent include 1-methoxy-2-propanol acetate (propylene glycol monomethyl ether acetate (PGMEA)), 1-methoxy-2-propyl acetate, ethoxyethyl propionate, cyclohexanone, 2-heptanone, γ-butyrolactone, butyl acetate, propylene glycol monomethyl ether, ethyl lactate, and 4-methyl-2-pentanol. The types of the solvent used in the embodiment can be one, two or more. Among those, one or more selected from the group consisting of PGMEA, γ-butyrolactone, cyclohexanone and 4-methyl-2-pentanol is preferable. Examples of more preferable solvents include those containing at least PGMEA.

The type of photoinitiator is not particularly limited, but examples include a photoradical polymerization initiator. The photoradical polymerization initiator is not particularly limited as long as it generates radicals with light irradiation. However, a type that generates radicals with radiation of light having the wavelength used for curing is preferable. The wavelength range of the light used for curing is, for example, 355 nm to 500 nm, and preferably, 365 nm to 430 nm. Specific examples of the photoradical polymerization initiator include Irgacure (registered trademark) 1173, Irgacure (registered trademark) 184, Irgacure (registered trademark) 2959, Irgacure (registered trademark) 127, Irgacure (registered trademark) 907, Irgacure (registered trademark) 369, Irgacure (registered trademark) 379, Lucirin (registered trademark) TPO, Irgacure (registered trademark) 819, Irgacure (registered trademark) OXE-01, Irgacure (registered trademark) OXE-02, Irgacure (registered trademark) 651, Irgacure (registered trademark) 754, and the like, all of which are trade names of BASF.

The content of the photoinitiator in the composition can be 0.01 parts by mass to 10 parts by mass with respect to 100 parts by mass of the photo-curable resin. A preferable range is 0.1 parts by mass to 5 parts by mass, and a more preferable range is 0.5 to 3 parts by mass.

The composition is obtained by, for example, adding the at least one cellulose fiber and the photo-curable resin to the solvent, and other components, if necessary, and mixing these materials.

Since the composition of the first embodiment described above includes the at least one cellulose fiber and the photo-curable resin, it is possible to obtain a cured material having an improved mechanical strength. A mechanism to produce such an effect should be as follows. In the composition, when the bundle of at least one cellulose fiber is separated into pieces of single fiber via splitting of the at least one cellulose fiber, an interfacial phase is formed on cellulose fiber. As the at least one cellulose fiber each having an interfacial phase approach each other to within a short distance, a chain architecture of cellulose fiber coupled in chains is formed. Due to a development of the chain architecture, a three-dimensional cell structure in which at least one cellulose fiber is three-dimensionally arranged is formed. Accordingly, the cured material elasticity coefficient can be improved. The other components, such as the photo-curable resin, can exist in spaces formed among the entangled cellulose fiber. Increasing the content of the at Least one cellulose fiber in the composition can facilitate the formation of the chain architecture and the three-dimensional cell structure.

### Second Embodiment

According to the second embodiment, an imprint method is provided. The imprint method includes preparing a template having a pattern in contact with a composition including at least one cellulose fiber and photo-curable resin (hereinafter referred to as “the first step”); and curing the composition by irradiating with light after preparing the template in contact with the composition (hereinafter referred to as “the second step”). Through this method, a layer structure into which the pattern of the template has been transferred can be obtained. The composition of the first embodiment is used as the composition of the method according to the second embodiment.

Examples of the imprint method of this embodiment include nano-imprintlithography.

Steps of the method of this embodiment will be explained below.

In the first step, the template having the pattern in contact with the composition is prepared. At that time, the composition may be disposed above a substrate. The substrate may be, for example, a silicon substrate. Examples of the method for disposing the composition above the substrate include coating, such as spin coating. Examples of the method for preparing the template having the pattern in contact with the composition include pressing the composition with the template. The template (also referred to as “the mold”) is not particularly limited, as long as it is a translucent member. For example, the template may be formed of a transparent material, such as glass, quartz, or the like. A line-and-space pattern formed in the template may be a fine pattern of the nanometer order. The width of the line can be, for example, 10 nm to 50 nm.

In the second step, the wavelength range of the light irradiation is, for example, 355 nm to 500 nm, and preferably, 365 nm to 430 nm. Specifically, the light irradiation may be performed by, for example, ultraviolet irradiation. The curing of the composition can be facilitated by adjusting the wavelength of the light, exposure illuminance, exposure time, and the like.

After the second step, it is possible to perform a step of releasing the contact between the cured material and the template by, for example, removing the template from the cured material.

The imprint method of the second embodiment described above includes curing the composition by irradiating with light, after preparing the template having the pattern in contact with the composition including the at least one cellulose fiber and the photo-curable resin. According to the method of the second embodiment, the mechanical strength, such as the coefficient of elasticity, can be improved while the fine pattern is being transferred into the cured material.

### Third Embodiment

According to the third embodiment, a semiconductor device is provided. The semiconductor device includes a substrate, an insulating layer provided above the substrate and including at least one cellulose fiber, and a conductive layer provided in the insulating layer.

First, the substrate, the insulating layer, and the conductive layer will be explained.

Examples of the substrate include a silicon substrate. The substrate is, for example, a semiconductor wafer.

The insulating layer includes an insulating material and at least one cellulose fiber. Examples of the insulating material include an organic film containing Si. In other words, the insulating material contains, for example, Si and C, or contains Si, C, and O. The cellulose fiber explained above for the first embodiment may be used.

The content of the at least one cellulose fiber in the insulating layer can be 0.1% by mass to 80% by mass. Preferably, the content is 0.2% by mass to 70% by mass. In the case where the content of at least one cellulose fiber is 0.1% by mass or more, a desired effect can be successfully obtained. In the case where the content is 80% by mass or less, the film-forming property can be improved.

The conductive layer can be formed of, for example, Cu, Al, W, or the like.

The semiconductor device may include a member other than the substrate, the insulating layer, and the conductive layer. For example, a barrier metal layer may be provided between the insulating layer and the conductive layer. The barrier metal layer can be formed of, for example, SiCN, SiOC, Ta, TaN, TiN, or the like.

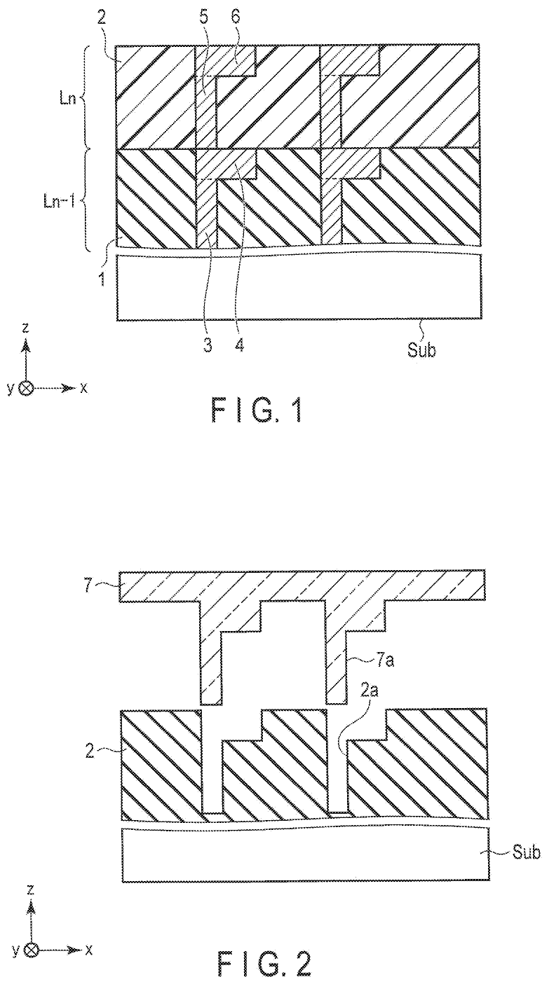

The structure of the semiconductor device is not particularly limited, but may have a structure, for example, as that shown in FIG. 1.

FIG. 1 is a schematic view showing a sectional structure of the semiconductor device according to the embodiment. As shown in FIG. 1, the semiconductor device includes a substrate Sub and a plurality of interconnect layers L arranged above an upper surface along an xy plane of the substrate Sub. An interconnect layer Ln-1 (n is a natural number) is located above the upper surface along the xy plane of the substrate Sub. The interconnect layer Ln-1 includes an insulating layer 1, a conductive plug 3, and an interconnect 4. The insulating layer 1 extends along the xy plane above the upper surface of the substrate Sub. The conductive plug 3 is provided in the insulating layer 1. The plug 3 extends in a z-axis direction. The interconnect 4 is provided in the insulating layer 1, and extends along the xy plane in the insulating layer 1. One interconnect 4 is coupled, at its bottom surface, to the upper surface of one plug 3. The plug 3 and the interconnect 4 constitute the conductive layer.

The interconnect layer Ln is located at a position higher than the interconnect layer Ln-1 (farther from the substrate Sub), and includes an insulating layer 2, a conductive plug 5, and an interconnect 6. The insulating layer 2 is provided above the upper surface of the insulating layer 1, and extends along the xy plane. The plug 5 is provided in the insulating layer 2. One conductive plug 5 is coupled, at its bottom surface, to the upper surface of one interconnect 4. The plug 5 extends in the z-axis direction. The interconnect 6 is provided in the insulating layer 2, and extends along the xy plane in the insulating layer 2. One interconnect 6 is coupled, at its bottom surface, to the upper surface of one plug 5. The plug 5 and the interconnect 6 constitute the conductive layer.

A diffusion preventing layer (omitted from illustration) can be provided between the interconnect layer Ln and the interconnect layer Ln-1. Another interconnect layer L (omitted from illustration) between the substrate Sub and the interconnect layer Ln-1 and another interconnect layer L (omitted from illustration) above the interconnect layer Ln may have the same structure as that of the interconnect layers Ln and Ln-1.

The semiconductor device exemplified in FIG. 1 is manufactured by, for example, the following method. The manufacturing method includes: disposing a composition including at least one cellulose fiber and photo-curable resin above a substrate; preparing a template having a pattern in contact with the composition; curing the composition by irradiating with light after preparing the template in contact with the composition, thereby forming an insulating layer into which the pattern is transferred; forming a metal plating layer in the insulating layer; and performing chemical mechanical polishing (CMP) on the metal plating layer. An example in which this manufacturing method is applied to formation of the interconnect layer Ln will be explained with reference to FIGS. 2 to 4.

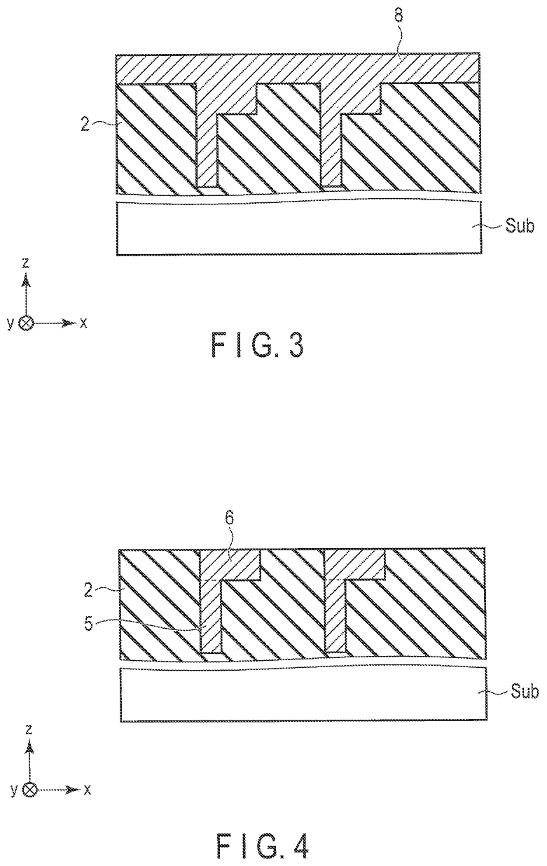

The composition of the first embodiment is disposed above the substrate Sub. A template 7 having a convexo-concave pattern 7a in contact with the composition is prepared. After preparing the template 7 in contact with the composition, the composition is cured by irradiating with light, thereby forming an insulating layer 2. A pattern 2a corresponding to the convexo-concave pattern 7a is transferred into the insulating layer 2. Then, as shown in FIG. 2, the template 7 is removed from the insulating layer 2. Thereafter, as shown in FIG. 3, a metal plating layer 8 is formed in a recess portion extending in an upper surface portion along the xy plane of the insulating layer 2 and extending in the z-axis direction. Next, a CMP process is performed on an upper surface along the xy plane of the metal plating layer 8, thereby forming the interconnect layer Ln including the insulating layer 2, the plug 5, and the interconnect 6 above the substrate Sub. The semiconductor device is manufactured by the method including a series of steps explained above.

The manufacturing method explained with reference to FIGS. 2 to 4 may be applied to an interconnect layer L other than the interconnect layer Ln and the interconnect layer Ln−1.

The semiconductor device according to the third embodiment described above, for example, as shown in FIG. 4, includes the substrate Sub, the insulating layer 2 provided above the substrate Sub and including at least one cellulose fiber, and the plug 5 and the interconnect 6 provided in the insulating layer 2. With the semiconductor device, the mechanical strength, such as the coefficient of elasticity, in the insulating layer can be improved. Specifically, in the CMP, which is a step in the manufacturing of the semiconductor device, the occurrence of dishing in the insulating layer can be avoided. If dishing occurs, reduced flatness of the insulating layer renders it difficult to form a new interconnect layer on the insulating layer. Moreover, a positioning mark for lithography formed on the upper surface of the insulating layer may be lost by dishing.

### Example

Examples will be explained in detail below.

### Example

A graft resin in which silicone resin is introduced to a side chain of 2-hydroxyethyl(meta)acrylate as photo-curable resin, phosphate-esterified fine cellulose fibers having a number average fiber diameter of 15 nm as cellulose nanofibers, and a photoradical polymerization initiator, Irgacure (registered trademark) 1173 as a photoinitiator, were dispersed in and mixed with a solvent: 1-methoxy-2-propanolacetate, thereby preparing a composition.

The resultant composition included 15 parts by mass of cellulose nanofibers and 5 parts by mass of the photoinitiator with respect to 100 parts by mass of the photo-curable resin.

Spin coating was performed on the composition to have a thickness of 100 nm to 300 nm on a silicon substrate. Nano-imprintlithography was performed using a nano-imprinting apparatus produced by Canon Inc. A wafer processed with spin coating was placed on a stage. The stage with the wafer placed thereon was moved in a horizontal direction to a position under a liquid dropping unit. Subsequently, the liquid dropping unit dropped a liquid droplet of the composition. Next, the stage with the wafer placed thereon was moved in a horizontal direction to a position under a template holding unit. A line-and-space pattern formed in the template was a fine pattern of the nanometer order having a line width of 10 nm to 50 nm. The template holding unit was moved downward, thereby pressing the template against the composition. In the state in which the template was pressed against the composition, an exposure light was emitted from a light emitting unit, thereby curing the composition. A high-pressure mercury lamp was used as the light emitting unit. The maximum wavelength of an irradiation light source was set to 365 nm, the exposure illuminance was set to 10 mW/cm², and the exposure time was set to 1.2 seconds (exposure amount 12 mJ/cm²). Finally, the template holding unit was moved upward, thereby removing the template from the composition. As a result, the convexo-concave pattern of the template was transferred into the composition. Thus, imprinting was completed, and an interlayer insulation film was obtained.

A Cu plating layer was formed on the interlayer insulation film by Cu plating. The Cu plating layer was polished by the CMP to make the step height lower than 30 nm. As a result, no dishing was observed. In the polishing, slurry including silica nano-particles as abrasive grains was used. Thus, the semiconductor device was manufactured by forming the interlayer insulation film and the Cu interconnect above the substrate.

### Comparative Example

A composition the same as the example, with the exception that cellulose nanofibers were not added, was prepared. The resultant composition was cured by the same method as in the example, thereby forming an interlayer insulation film. Subsequently, a Cu plating layer was formed in the same manner as in the example. The Cu plating layer was polished by the CMP using a slurry similar to that used in the example to render the step height lower than 30 nm. As a result, dishing was observed. Accordingly, since the flatness of the interlayer insulation film was insufficient, a new interconnect layer could not be formed on the interlayer insulation film. Moreover, the positioning mark for lithography formed on the interlayer insulation film was lost by dishing.

The embodiments are described as supplemental below.

According to one embodiment, there is provided a semiconductor device including a substrate; an insulating layer formed above the substrate; and a conductive layer provided in the insulating layer. The insulating layer includes at least one cellulose fiber.

According to another embodiment, there is provided an imprint method which includes preparing a template having a pattern in contact with a composition including at least one cellulose fiber and photo-curable resin; and

curing the composition by irradiating with light after preparing the template in contact with the composition.

According to still another embodiment, there is provided a curable composition for imprinting, that includes at least one cellulose fiber and photo-curable resin.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
an insulating layer provided above the substrate and including at least one cellulose fiber; and
a conductive layer provided in the insulating layer.

2. The semiconductor device according to claim 1, wherein the insulating layer contains Si and C.

3. The semiconductor device according to claim 1, wherein the insulating layer contains Si, C, and 0.

4. The semiconductor device according to claim 1, wherein the at least one cellulose fiber is at least one cellulose nanofiber.

5. The semiconductor device according to claim 1, wherein a diameter of one of the at least one cellulose fiber is 3 nm to 15 nm.

6. The semiconductor device according to claim 1, wherein a content of the at least one cellulose fiber in the insulating layer is 0.1% by mass to 80% by mass.

7. The semiconductor device according to claim 1, wherein the at least one cellulose fiber is at least one cellulose nanofiber, and a content of the at least one cellulose fiber in the insulating layer is 0.1% by mass to 80% by mass.

8. The semiconductor device according to claim 1, wherein a diameter of one of the at least one cellulose fiber is 3 nm to 15 nm and a content of the at least one cellulose fiber in the insulating layer is 0.1% by mass to 80% by mass.

9. An imprint method comprising:
preparing a template having a pattern in contact with a composition including at least one cellulose fiber and photo-curable resin; and
curing the composition by irradiating with light after preparing the template in contact with the composition.

10. The imprint method according to claim 9, further comprising disposing the composition above a substrate before preparing the template in contact with the composition.

11. The imprint method according to claim 9, wherein a wavelength range of the light is 355 nm to 500 nm.

12. The imprint method according to claim 9, wherein a diameter of one of the at least one cellulose fiber is 3 nm to 15 nm.

13. The imprint method according to claim 9, wherein the at least one cellulose fiber is at least one cellulose nanofiber.

14. The imprint method according to claim 9, wherein a content of the at least one cellulose fiber in the composition is 1 part by mass to 50 parts by mass with respect to 100 parts by mass of the photo-curable resin.
